(19) United States
(12) Patent Application Publication
(10) Pub. No.: US 2015/0104574 A1
(43) Pub. Date: Apr. 16, 2015

(54) FAST ATOMIC LAYER DEPOSITION PROCESS USING SEED PRECURSOR

(71) Applicant: Veeco ALD Inc., Fremont, CA (US)

(72) Inventors: Sang In Lee, Los Altos Hills, CA (US); Chang Wan Hwang, Busan (KR); Jeong Ah Yoon, Hwaseong-si (KR)

(21) Appl. No.: 14/514,296

(22) Filed: Oct. 14, 2014

Related U.S. Application Data
(60) Provisional application No. 61/891,223, filed on Oct. 15, 2013.

(51) Int. Cl. C23C 16/455; C23C 16/458; C23C 16/18

(52) U.S. Cl. CPC C23C 16/45534; C23C 16/18; C23C 16/4584; C23C 16/45551; C23C 16/45553
USPC 427/255.28; 118/719

(57) ABSTRACT

Embodiments relate to an atomic layer deposition (ALD) process that uses a seed precursor for increased deposition rate. A first reactant precursor (e.g., H₂O) may be formed as a result of reaction. The first reactant precursor may react with or substitute source precursor (e.g., 3DMAS) in a subsequent process to deposit material on a substrate. In addition, a second reactant precursor (e.g., radicals) may be separately injected onto the substrate previously injected with the source precursor. By causing the source precursor to react with the first reactant precursor from the surface of the substrate and also react with the second reactant provided by the injector, the material is deposited on the substrate in an expedient manner.

### CROSS-REFERENCE TO RELATED APPLICATION

This application claims priority and benefit under 35 U.S.C. §119(e) to U.S. Provisional Patent Application No. 61/891,223, filed Oct. 15, 2013, which is incorporated herein by reference in its entirety.

### BACKGROUND

1. Field of Art

The disclosure relates to an atomic layer deposition (ALD) process using a seed precursor to improve a deposition rate of material on a substrate.

2. Description of the Related Art

Attempts are currently being made to implement Self Assembled Molecule (SAM) process or selective ALD process, which takes advantage of selective adsorption of H₂O on hydrophilic regions of a surface. Such SAM process or selective ALD process enables patterns of material to be deposited without using lithography and etching processes. For example, nano-patterning technique has been developed to selectively grow films on hydrophilic regions of a surface.

However, the purging or pumping of H₂O in such processes requires an extended amount of time. Especially when performed at a low temperature, below 100° C., the slow purging or pumping speed of H₂O and easy adsorption of H₂O in the walls of a reaction chamber or injectors prolongs the amount of time needed to purge or pump H₂O. The slow purging or pumping of H₂O from the reaction chamber or the injectors is one of the major deterrents against adoption of the SAM process and the selective ALD process in a mass production process. If H₂O is incompletely purged or pumped from the reaction chamber or the injectors, the remaining H₂O may react with source precursor or reactant precursor subsequently injected into the reaction chamber or the injectors, creating undesirable particles in the chamber or the injectors as a result of such reaction.

The ALD process generally includes a cycle including four steps: (i) injection of source precursor onto a substrate, (ii) purging of the source precursor from the substrate to leave only chemisorbed source precursor on the substrate, (iii) injection of the reactant precursor, and (iv) purging of material formed as the result of reaction between the source precursor and the reactant precursor, leaving only chemisorbed material layer on the substrate. Such ALD process results in a low deposition rate around 0.5 to 2 Å/cycle.

In order to increase the deposition rate, the purge process may be performed incompletely or omitted during the ALD process to leave part of the physisorbed source precursor or resulting material on the substrate. However, even such incomplete purging results in a deposition rate of lower than 10 Å/cycle.

### SUMMARY

Embodiments relate to an atomic layer deposition (ALD) process that uses a seed precursor for increased rate of deposition of a material on a substrate. In one embodiment, the ALD process includes injecting a seed precursor onto the substrate and injecting a first source precursor onto the substrate. The first source precursor reacts with the seed precursor to generate a first reactant precursor, such as H₂O, on a surface of the substrate, which means the injection and the purge/pumping of the first reactant precursor are not required. A second source precursor is injected onto the substrate. The second source precursor reacts with the first reactant precursor on the surface of the substrate to deposit the material on the surface of the substrate. In one embodiment, the material is deposited on the surface of the substrate by atomic layer deposition (ALD).

In one embodiment, a second reactant precursor is injected onto the substrate after the second source precursor is injected onto the surface of the substrate. The second reactant precursor reacts with the second source precursor to deposit the material on the substrate. The second reactant precursor may comprise radical generated from an oxygen-containing species, such as hydroxyl radicals or radicals generated from O₃, plasma of (N₂O or O₂ or O₃), or mixed plasma with H₂ or NH₃, such as (O₂+H₂) plasma or (N₂O+NH₃) plasma.

In one embodiment, the surface of the substrate is treated prior to injecting the seed precursor by injecting hydroxyl radicals onto the substrate to generate hydroxylated termination sites on the surface of the substrate. The seed precursor reacts with the hydroxylated termination sites to generate an intermediate compound, and the first source precursor reacts with the intermediate compound to generate the first reactant precursor.

In one embodiment, a series of reactors inject the seed precursor, the first source precursor, and the second source precursor onto the substrate. A relative movement is caused between the substrate and the series of reactors as the reactors inject the seed precursor, the first source precursor, and the second source precursor onto the substrate.

In one embodiment, after the second source precursor is injected, injection of the first source precursor and the second source precursor onto the surface of the substrate is repeated without injecting the seed precursor.

In one embodiment, the seed precursor is trimethylaluminum (TMA), the first source precursor is a silanol, and the first reactant precursor is water. Furthermore, in one embodiment, the second source precursor comprises one selected from the group consisting of trimethlaluminum (TMA), tridimethylaminosilicon (3DMAS), titanium tetrachloride (TiCl₄), tetrakis(dimethylamido)titanium (TDMAT), tetrakis(ethylmethylamido)zirconium (TEMAZr), and (Methylcyclopentadienyl)-trimethylplatinum (MeCpPtMe₃).

In one embodiment, the process for depositing material on a substrate is performed by an apparatus including a plurality of reactors. A first reactor injects a seed precursor onto a surface of the substrate. A second reactor, which is adjacent to the first reactor, injects a first source precursor onto the substrate. The first source precursor reacts with the seed precursor to generate a first reactant precursor on the surface of the substrate. A third reactor, which is adjacent to the second reactor, injects a second source precursor onto the substrate. The second source precursor reacts with the first reactant precursor on the surface of the substrate to deposit the material on the surface of the substrate.

### BRIEF DESCRIPTION OF DRAWINGS

FIG. 1 is a cross sectional diagram of a linear deposition device performing a fast atomic layer deposition (ALD) process, according to one embodiment.

FIG. 2 is a perspective view of the linear deposition device, according to one embodiment.

FIG. 3 is a perspective view of a rotating deposition device, according to one embodiment.

FIG. 4 is a perspective view of reactors in the deposition device of FIG. 1, according to one embodiment.

FIG. 5 is a cross sectional diagram illustrating the reactors taken along line A-B of FIG. 4, according to one embodiment.

FIG. 6 is a flowchart illustrating deposition of material using a fast ALD process, according to one embodiment.

### DETAILED DESCRIPTION OF EMBODIMENTS

Embodiments are described herein with reference to the accompanying drawings. Principles disclosed herein may, however, be embodied in many different forms and should not be construed as being limited to the embodiments set forth herein. In the description, details of well-known features and techniques may be omitted to avoid unnecessarily obscuring the features of the embodiments.

In the drawings, like reference numerals in the drawings denote like elements. The shape, size and regions, and the like, of the drawing may be exaggerated for clarity.

Embodiments relate to an atomic layer deposition (ALD) process that uses a seed precursor for increased deposition rate. A first reactant precursor (e.g., H₂O) may be formed as a result of catalytic effect from a seed precursor. The first reactant precursor may react with or substitute source precursor (e.g., 3DMAS) in a subsequent process to deposit material on a substrate. In addition, a second reactant precursor (e.g., radicals) may be separately injected onto the substrate previously injected with the source precursor. By causing the source precursor to react with the first reactant precursor from the surface of the substrate and also react with the second reactant provided by the injector, the material is deposited on the substrate in an expedient manner.

As used herein, a seed precursor refers to a compound that reacts with a source precursor injected onto a substrate to generate a reactant precursor for depositing one or more layers or material by a deposition process. The deposition process may include, among others, chemical vapor deposition (CVD), atomic layer deposition (ALD), and molecular layer deposition (MLD). The seed precursor may obviate the need to separately inject the reactant precursor onto the substrate or supplement the reactant precursor separately injected onto the substrate to promote deposition of a layer.

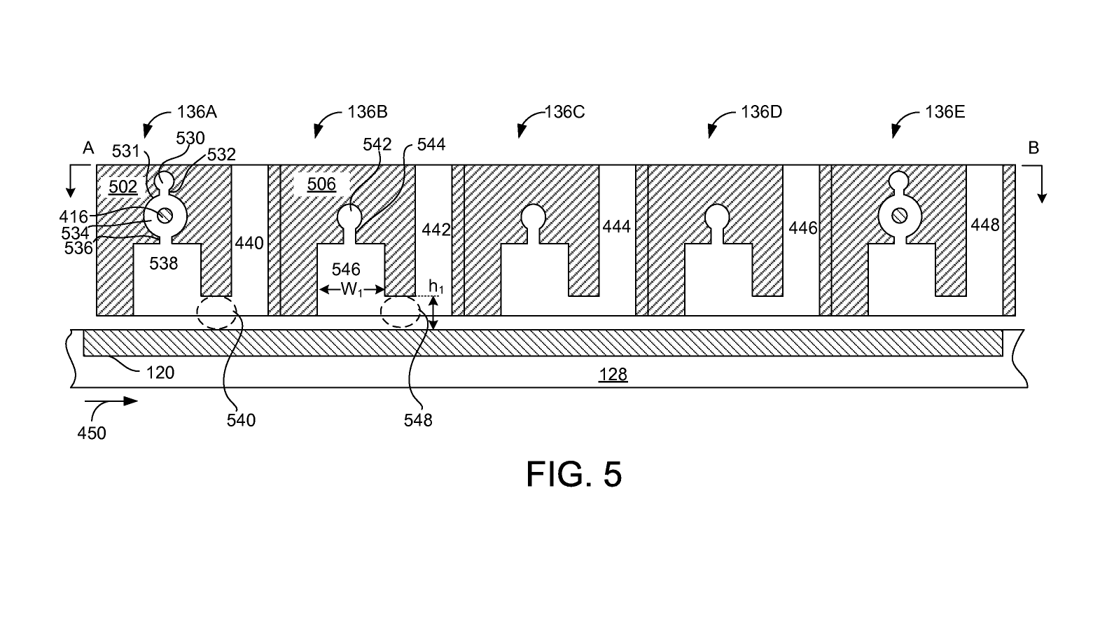

Figure (FIG.) 1 is a cross sectional diagram of a linear deposition device 100 for performing ALD process, according to one embodiment. FIG. 2 is a perspective view of the linear deposition device 100 (without chamber walls to facilitate explanation), according to one embodiment. The linear deposition device 100 may include, among other components, a support pillar 118, the process chamber 110 and one or more reactors 136. The reactors 136 may include one or more of injectors and radical reactors. Each of the injectors injects source precursors or reactant precursors onto the substrate 120. As described below in detail with reference to FIG. 5, source precursors and/or reactant precursors may be radicals of a gas mixture.

The process chamber enclosed by the walls may be maintained in a vacuum state to prevent contaminants from affecting the deposition process. The process chamber 110 contains a susceptor 128 which receives a substrate 120. The susceptor 128 is placed on a support plate 124 for a sliding movement. The support plate 124 may include a temperature controller (e.g., a heater or a cooler) to control the temperature of the substrate 120. The linear deposition device 100 may also include lift pins (not shown) that facilitate loading of the substrate 120 onto the susceptor 128 or dismounting of the substrate 120 from the susceptor 128.

In one embodiment, the susceptor 128 is secured to brackets 210 that move across an extended bar 138 with screws formed thereon. The brackets 210 have corresponding screws formed in their holes receiving the extended bar 138. The extended bar 138 is secured to a spindle of a motor 114, and hence, the extended bar 138 rotates as the spindle of the motor 114 rotates. The rotation of the extended bar 138 causes the brackets 210 (and therefore the susceptor 128) to make a linear movement on the support plate 124. By controlling the speed and rotation direction of the motor 114, the speed and the direction of the linear movement of the susceptor 128 can be controlled. The use of a motor 114 and the extended bar 138 is merely an example of a mechanism for moving the susceptor 128. Various other ways of moving the susceptor 128 (e.g., use of gears and pinion at the bottom, top or side of the susceptor 128). Moreover, instead of moving the susceptor 128, the susceptor 128 may remain stationary and the reactors 136 may be moved.

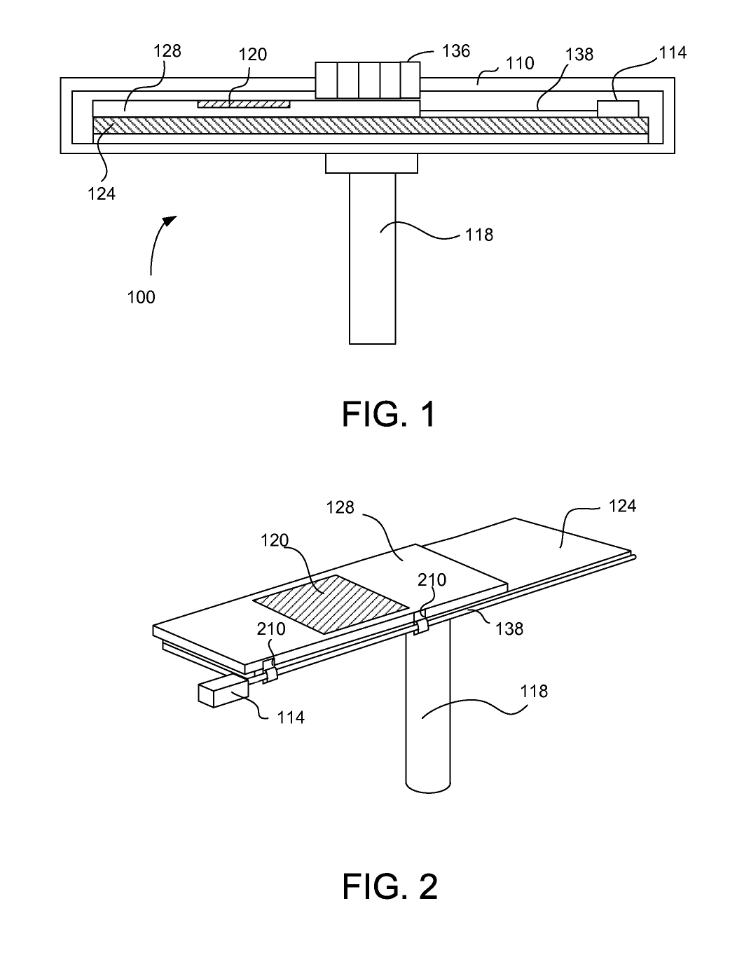

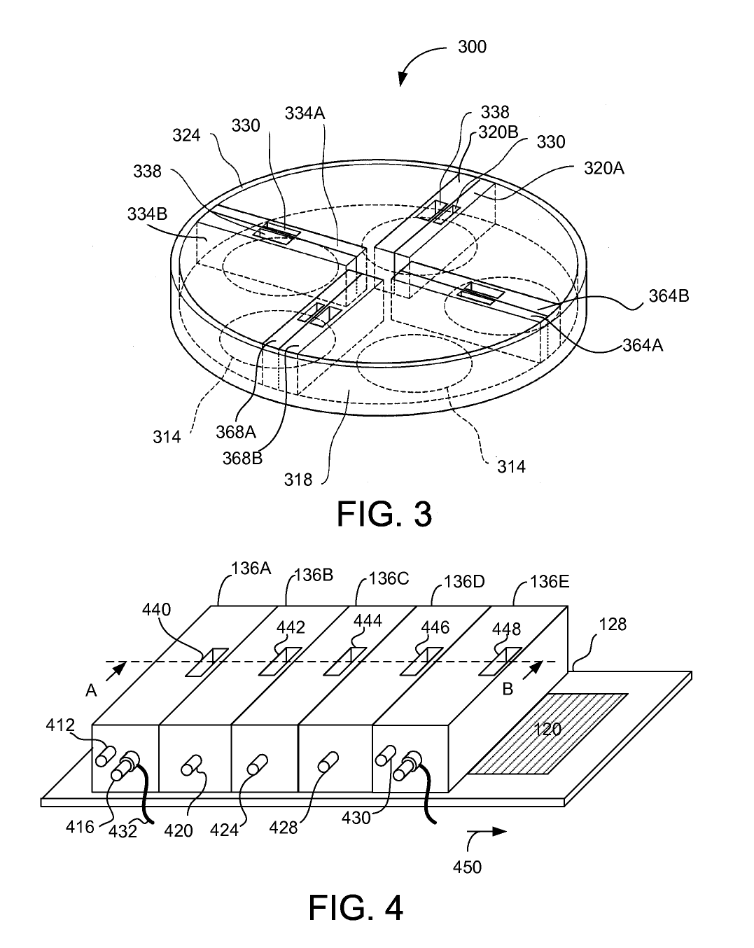

FIG. 3 is a perspective view of a rotating deposition device 300, according to one embodiment. Instead of using the linear deposition device 100 of FIG. 1, the rotating deposition device 300 may be used to perform the deposition process according to another embodiment. The rotating deposition device 300 may include, among other components, reactors 320A, 320B, 334A, 334B, 364A, 364B, 368A, 368B, a susceptor 318, and a container 324 enclosing these components. A set of reactors (e.g., 320A and 320B) of the rotating deposition device 300 correspond to the reactors 136 of the linear deposition device 100, as described above with reference to FIG. 1. The susceptor 318 secures the substrates 314 in place. The reactors 320A, 320B, 334A, 334B, 364A, 364B, 368A, 368B are placed above the substrates 314 and the susceptor 318. Either the susceptor 318 or the reactors 320, 334, 364, 368 rotate to subject the substrates 314 to different processes.

One or more of the reactors 320A, 320B, 334A, 334B, 364A, 364A, 368B, 368B are connected to gas pipes (not shown) to provide source precursor, reactor precursor, purge gas and/or other materials. The materials provided by the gas pipes may be (i) injected onto the substrate 314 directly by the reactors 320A, 320B, 334A, 334B, 364A, 364B, 368A, 368B, (ii) after mixing in a chamber inside the reactors 320A, 320B, 334A, 334B, 364A, 364B, 368A, 368B, or (iii) after conversion into radicals by plasma generated within the reactors 320A, 320B, 334A, 334B, 364A, 364B, 368A, 368B. After the materials are injected onto the substrate 314, the redundant materials may be exhausted through outlets 330, 338. The interior of the rotating deposition device 300 may also be maintained in a vacuum state.

Although following example embodiments are described primarily with reference to the reactors 136 in the linear deposition device 100, the same principle and operation can be applied to the rotating deposition device 300 or other types of deposition device.

FIG. 4 is a perspective view of reactors 136A through 136E (collectively referred to as the “reactors 136”) in the deposition device 100 of FIG. 1, according to one embodiment. In FIG. 4, the reactors 136A through 136E are placed in tandem adjacent to each other. In other embodiments, the reactors 136A through 136E may be placed with a distance from each other. As the substrate 120 moves from the left to the right (as shown by arrow 450), the substrate 120 is sequentially injected with materials by the reactors 136A through 136E to form a deposition layer on the substrate 120. Instead of moving the substrate 120, the reactors 136A through 136E may move from the right to the left while injecting materials.

In one or more embodiments, the reactor 136A is a radical reactor that generates radicals of gas and injects the radicals onto the substrate 120. The radical reactor 136A is connected to a pipe 412 to receive gas from a source. An electrode 416 extends across the length of the radical reactor 136A. By applying voltage across the electrode 416 and the body of the radical reactor 136A, the injected gas is converted into radicals. The radicals are injected onto the substrate 120, and remaining radicals and/or gas reverted to an inactive state are discharged from the radical reactor 136B via an exhaust portion 440.

The reactors 136B through 136D may be injectors for injecting gas or mixture of gas or purge gas onto the substrate 120 received via pipes 420, 424, 428. Excess gas remaining after injection onto the substrate 120 is exhausted via exhaust portions 442, 444, 446, as described below in detail with reference to FIG. 5.

The reactor 136E may be a radical reactor having the same or similar structure as the reactor 136A. The reactor 136E may be provided, via pipe 430, with the gas same or different from the gas provided to the reactor 136A.

FIG. 5 is a cross sectional diagram illustrating the reactors 136A through 136E taken along line A-B of FIG. 4, according to one embodiment. The radical reactor 136A includes a body 502 formed with a gas channel 530, a plasma chamber 534, a passage 532 connecting the gas channel 530 and the plasma chamber 534, perforations (slits or holes) 536, a reaction chamber 538, a constriction zone 540, and an exhaust portion 440. The radical reactor 136A includes an inner electrode 416 and an outer electrode 531 surrounding the plasma chamber 534 (the outer electrode 531 may be part of a metallic body 502). A gas or a mixture of gases is injected via the channel 530 and perforations 532 into the plasma chamber 534. By applying a voltage difference between the inner electrode 416 and the outer electrode 531, plasma is generated in the plasma chamber 534.

As a result of the plasma, radicals of the gas or the mixture of gases are generated within the plasma chamber 534. The generated radicals are injected into the reaction chamber 538 via the perforations 536. The region of the substrate 120 below the reaction chamber 538 comes into contact with the radicals.

In one embodiment, a mixture of O₂ and H₂ gas (or O₃ and H₂ gas, or N₂O and NH₃ gas) is provided into the reactor 136A to generate hydroxyl (OH)* radicals. By injecting hydroxyl (OH)* radicals onto the substrate 120, the surface of the substrate 120 may be hydroxylated.

The reactor 136B is an injector for injecting a gas onto the substrate 120. The radical reactor 136B includes a body 506 formed with a gas channel 542, perforations (slits or holes) 544, a reaction chamber 546, a constriction zone 548, and an exhaust portion 442. The gas is injected into the reaction chamber 546 via the gas channel 542 and the perforations 544. The gas fills the reaction chamber 546 and is injected onto the substrate 120 below the reaction chamber 546. The injected gas flows through the reaction chamber 546, the constriction zone 548 and the exhaust portion 442. The constriction zone 548 has a height h₁ that is smaller than width W₁ of the reaction chamber 546. Therefore, Venturi effect is caused in the constriction zone 548, which at least partially removes gas adsorbed on the substrate 120 or material deposited on the substrate 120 if the gas injected by the radical reactor 136B is a source precursor or a reactant precursor.

The reactor 136C and 136D may have the same or similar structure as the injector 136B, and therefore, the detailed description thereof is omitted herein for the sake of brevity. Each of the radical reactors 136C and 136D may inject a different or the same gas onto the substrate 120 to perform a fast ALD process. The reactor 136C may inject a purge gas such as Ar or N₂ to leave a chemisorbed precursor on the substrate 120. Additional reactors inject purge gas may be installed next to each reactor for removing physisorbed source precursors and/or reactant precursors on the surface of the substrate 120. The reactor 136E may have the same or similar structure as the radical reactor 136A, and therefore, the detailed description thereof is omitted herein for the sake of brevity.

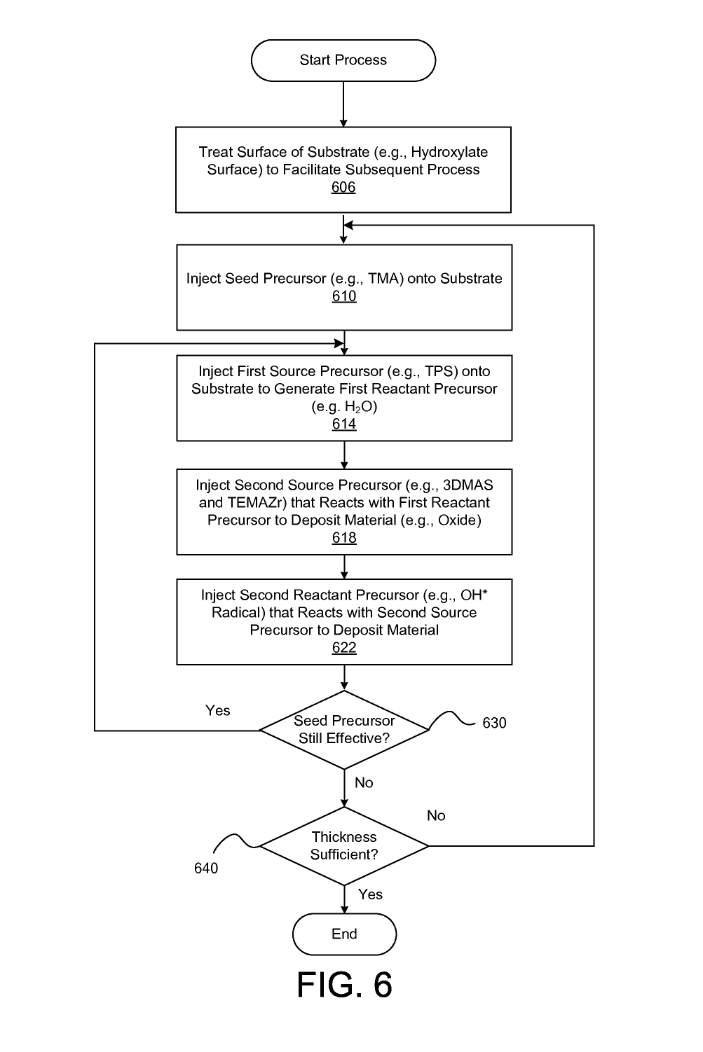

FIG. 6 is a flowchart illustrating deposition of material using a fast ALD process, according to one embodiment. The following embodiments are described primarily with reference using Trimethylaluminum (TMA) as O₂ and H₂ gas precursor to form an oxide layer or an atomic Al layer on a substrate but different materials may also be deposited on the substrate using a different seed precursor.

In one or more embodiments, the substrate may be deposited with layers of material (e.g., an encapsulation layer) before performing the subsequent steps. For example, one or more layers of Al₂O₃ may be deposited on the substrate. Al₂O₃ layers may function as an encapsulation layer that prevents moisture from penetrating into the substrate. One or more layers of Al₂O₃ may be formed by injecting aluminum containing precursor such as TMA, dimethylaluminumhydride ((CH₃)₂AlH), dimethylehylaminealane [AlH₃N(CH₃)₂(C₂H₅)], and dimethylaluminum i-propoxide ((CH₃)₂Al(0C₃H₇) followed by exposure of the substrate to an oxidizing agent.

Then the surface of the substrate, which can be treated with the encapsulation layer, is treated 606 to facilitate the subsequent fast ALD process. The treating process may include hydroxylated sites on a substrate by injecting hydroxyl (OH*) radicals. The hydroxyl (OH*) radicals may be generated by injecting a mixture of O₂ gas and H₂ gas into the radical reactor 136A. Alternatively, hydroxyl (OH*) radicals may be generated by generating O* radicals and H* radicals separately, and then mixing these radicals. By exposing the surface of the substrate to hydroxyl radicals, the surface of the substrate is treated to include sites with OH terminations. Exposure of the substrate to a vapor of H₂O may alternatively be used as an initial hydroxylation process.

A seed precursor such as TMA is injected 610 onto the treated substrate. For example, the injector 136B may inject TMA onto the substrate 120. Other seed precursor such as dimethylaluminumhydride ((CH₃)₂AlH), dimethylethylaminealane [AlH₃N(CH₃)₂(C₂ H₅)], and dimethylaluminum i-propoxide (CH₃)₂Al(OC₃H₇) may alternatively be used. Alternatively, other seed precursors having transition metal such as Ni or Co can be used instead of Al. Injection of TMA onto a silicon substrate including hydroxylated sites results in a reaction producing an intermediate product and CH₄, as expressed by the following equation:

SiOH*+Al(CH₃)₃→SiOAl(CH₃)₂*+CH₄ (1)

Then, a first source precursor is injected 614 onto the substrate. For example, the injector 136C injects tris(tert-pentoxy)silanol (TPS) onto the substrate as the first source precursor onto the substrate, which causes the silanols to react at the aluminum center to release CH₄, as expressed by the following equation:

SiOAlCH₃*(CH₃CH₂(CH₃)₂CO)₃SiOH→SiOAlOSi(OC(CH₃)₂CH₂CH₃)₃*+CH₄ (2)

Additional silanol precursors can then be inserted at the Al seed or catalytic center and release tert-pentanol as given by the following equation:

SiOAlOSi(OC(CH₃)₂CH₂CH₃)₃*+(CH₃CH₂(CH₃)₂CO)₃SiOH→SiOAlOSi(OC(CH₃)₂CH₂CH₃)₂—O—Si(OC(CH₃)₂CH₂CH₃)₃*+(CH₃)₃CCH₂OH (3)

The polymerization reaction is believed to occur as long as the silanol precursors can diffuse to the Al catalyst. Cross-linking reactions between the siloxane chains are in competition with the silanol diffusion. First, the tert-pentoxy ligands eliminate isopentylene and leave behind hydroxyl groups as expressed by the following equation:

—OSi(OC(CH₃)₂CH₂CH₃)₃*→—OSiOH*+H₂C═CCH₃CH₂CH₃ (4)

The hydroxyl groups can subsequently react with other hydroxyl groups to yield H₂O and cross-linking siloxane bonds that terminate the SiO₂ growth as given by the following reaction:

2SiOH*→Si—O—Si+H₂O (5)

H₂O formed as a result is used as a first reactant precursor for reacting with or substituting a second source precursor that is subsequently injected onto the substrate. It is to be noted that H₂O is not injected by any injectors but formed as a result of reaction of the first source precursor, i.e., a concomitant by-product of hydrogen bonding with OH groups. Since H₂O is not injected by any injectors, a purging process to eliminate H₂O may be obviated.

Other silanols or silanediols such as alkoxysilanols, alkyl alkoxysilanols, alkyl alkoxysilanediols and alkoxysilanediols may also be used as the first source precursor. Examples of material suitable as the first source precursor include, among others, tris(tert-butoxy) silanol ((C₄H₉O)₃SiOH), tris(tert-pentoxy)silanol((C₅H₁₁O)₃SiOH), di(tert-butoxy)silandiol ((C₄H₉O)₂Si(OH)₂) and methyl di(tert-pentoxy)silanol.

Referring back to FIG. 6, the injector 136D injects 618 a second source precursor onto the substrate to deposit a material on the substrate. Materials for any ALD oxide layer formation such as Al₂O₃, SiO₂, TiO₂, and ZrO₂ can be deposited with TMA (TriMethylAluminum), 3DMAS (TriDiMethylAmino Silicon), Titanium tetrachloride (TiCl₄), TDMAT [Tetrakis(dimethylamido)titanium], or TEMAZr (Tetrakis(ethylmethylamido)zirconium) as the second source precursor, respectively. Alternatively, a platinum layer may be deposited by using (Methylcyclopentadienyl)-trimethylplatinum (MeCpPtMe₃) as the second source precursor. The second source precursor reacts with H₂O formed by the process described above with reference to equation (5), and thereby deposits a layer of oxide or noble metal such as Pt or Ru on the substrate. When 3DMAS is used as the second source precursor, SiO₂ doped with Aluminum is deposited on the substrate. When TEMAZr is mixed with 3DMAS as the second source precursor, SiO₂ doped with Al and Zr is deposited on the substrate. When MeCpPtMe₃ is used as the second source precursor, platinum is deposited on the SiO₂ layer.

After injecting the second source precursor, the substrate is injected with the second reactant precursor by the radical reactor 136E. The second reactant precursor may be, for example, hydroxyl (OH)* radicals generated from the mixed gas plasma, such as (N₂O+H₂), (O₂+H₂), (O₃+H₂), or (N₂O+NH₃). The second reactant precursor also reacts with the second source precursor and deposits an oxide material or noble metal on the substrate. Instead of using hydroxyl (OH)* radicals, other materials such as ozone, O* radicals, or radicals generated from the plasma containing O species such as N₂O or O₂ or O₃ may also be used as the second reactant precursor. The reaction associated with use of O* radicals tends to be slower than when (OH)* radicals are used. However, the use of O* radicals does not yield hydroxyl group that may be problematic in some processes.

By providing the first reactant precursor (e.g., H₂O) by the reaction from the treated surface of the substrate, and injecting the second reactant precursor (e.g., (OH)* radical) from the injector 136E above the substrate 120, the material such as SiO₂ can be deposited on the substrate at a fast rate. The hydroxyl (OH*) radicals also cause SiO₂ layer to be terminated with OH terminations. The seed SiO₂ may enable the steps of injecting 614 the first source precursor and subsequent steps to be repeated.

It is then determined 630 if the catalytic effect of the seed precursor is still applicable. If so, the injection 614 of the first source precursor through the injection 622 of the second reactant precursor is repeated to deposit another layer of the material. If it is determined 640 that the catalytic effect is no longer applicable due to the thick deposition of the material, the process may return to inject 610 the seed precursor and repeats the subsequent steps until the desired thickness of material is deposited on the substrate. In case of thick SiO₂ formation (e.g., thicker than 100 Å), because of no diffusion-out or penetration of H₂O through film, there will be no effective H₂O out from film. The thickness of the material at which the seed precursor remains effective depends on the substrate temperature. At a higher temperature, the seed precursor reacts more effectively to produce H₂O. As an example, at 150° C., a thickness range of the first source precursor is 1 Å˜20 Å and the amount of first source precursor or the number of injections 614 might be changed. The total numbers of the injection 618 and 622 of the second source precursor and the second reactant precursor can be determined according to the thickness of the material. As described above, the total thickness of the film from the injections 618 and 622 of the second source precursor and the second reactant precursor on the film generated by the injection 614 of the first source precursor will be thicker than that of other underlying layers. After injecting 622 the second reactant precursor, the film structure will be (1 Å˜20 Å of SiO₂with Al seed layer)/(2 Å˜40 Å of an oxide film obtained from second source), depending on the number of the injections. So, in this example, the thinnest film structure will be 3 Å, and its structure will be 1 Å-SiO₂/2 ÅA-oxide. Furthermore, the thickest film in this example will be 60 Å and the structure will be 20 Å-SiO₂/40 Å-oxide. For embodiments using TEMAZr as the second source precursor, the film in this example will be (1 Å˜20 Å SiO₂)/(2 Å˜40 Å ZrO₂).

When the desired thickness of material is obtained, the process terminates. When an encapsulation layer is deposited on the substrate, the desired thickness of the material may at least 250 Å. In this case, the desired thickness may be achieved by performing steps 610-640 four times, which will produce a 4×(20 Å SiO₂)/(40 Å ZrO₂)=240 Å thick film and eight stacks of the film

In one embodiment, injection 618 of the second source precursor and injection 622 of the second reactant precursor are repeated more often than injection 614 of the first source precursor. Assuming that the first source precursor is TPS, the second source precursor is TEMAZr, and the second reactant precursor is (OH*) radicals, steps 618 and 622 are repeated “a” times and steps 614 through steps 622 is repeated “b” times. As a result, a layer with the composition of b×(SiO₂/(a×ZrO₂)) is deposited on the substrate. By adjusting the repeated number of times “a” and “b,” Zr content in the layer can be modified.

In one embodiment, injection 618 of the second source precursor and injection 622 of the second reactant precursor are repeated more often than injection 614 of the first source precursor. Assuming that the first source precursor is TPS, the second source precursor is Ti-containing precursor such as Ti(Rᵢ—N—C(R₃)—N—R₂)ᵤ(OR₄)ₓ(NR₅R₆)_{y}(O₂CR₇)_{z} wherein:
R₁, R₂, R₅, R₆, and R₇ are independently selected from the group consisting of H and C1-C6 alkyl group;
R₃═H, C1-C6 alkyl group, or NMe₂;
R₄ is a C1-C6 alkyl group;
u=2;
x=2;
y=0; and z=0
   The result will be similar to the above.

In one embodiment, injection 614 of the first source precursor for 1 Å˜20 Å of SiO₂, injection 618 of the second source precursor, and injection 622 (as an option) of the second reactant precursor are repeated to deposit the material from the second source precursor. Assuming that the first source precursor is TPS, the second source precursor is (Methylcyclopentadienyl)-trimethylplatinum (MeCpPtMe₃), step 614 is repeated “c” times and step 618 through step 622 is repeated “d” times. As a result, a layer of Pt is deposited on the substrate covered with SiO₂. By adjusting the repeated number of times “c” and “d,” the thickness of Pt can be controlled, and Pt content in the layer can be modified.

Also, the source chemical utilization or gas-to-solid efficiency can be increased by using this concept and process because a concomitant by-product, H₂O, reacts with the first coming source precursor on the surface of the substrate and the excess source molecules, which are generally the physisorbed molecules, turn into a film because a concomitant by-product, H₂O, reacts with the physisorbed molecules.

While particular embodiments and applications have been illustrated and described herein, it is to be understood that the embodiments are not limited to the precise construction and components disclosed herein and that various modifications, changes, and variations may be made in the arrangement, operation, and details of the methods and apparatuses of the embodiments without departing from the spirit and scope of the embodiments as defined in the appended claims.

What is claimed is:

1. A method for depositing a material on a substrate, comprising:
injecting a seed precursor onto the substrate;
injecting a first source precursor onto the substrate, the first source precursor reacting with the seed precursor to generate a first reactant precursor on a surface of the substrate; and
injecting a second source precursor onto the substrate, the second source precursor reacting with the first reactant precursor on the surface of the substrate to deposit the material on the surface of the substrate.

2. The method of claim 1, further comprising:
injecting a second reactant precursor onto the substrate after injecting the second source precursor onto the surface of the substrate, the second reactant precursor reacting with the second source precursor to deposit the material on the substrate.

3. The method of claim 2, wherein the second reactant precursor comprises radicals generated from an oxygen-containing species.

4. The method of claim 1, further comprising:
treating the surface of the substrate by injecting hydroxyl radicals onto the substrate prior to injecting the seed precursor to generate hydroxylated termination sites on the surface of the substrate, wherein the seed precursor reacts with the hydroxylated termination sites to generate an intermediate compound and the first source precursor reacts with the intermediate compound to generate the first reactant precursor.

5. The method of claim 1, further comprising causing a relative movement between the substrate and a series of reactors injecting the seed precursor, the first source precursor, and the second source precursor onto the substrate.

6. The method of claim 1, wherein the material is deposited on the surface of the substrate by atomic layer deposition (ALD).

7. The method of claim 1, wherein the first source precursor is trimethylaluminum (TMA) and the first source precursor is a silanol, and wherein the first reactant precursor is water.

8. The method of claim 1, wherein the second source precursor comprises one selected from the group consisting of TMA, 3DMAS, TiCl₄, TDMAT, TEMAZr, and MeCpPtMe₃.

9. The method of claim 1, further comprising, after injecting the second source precursor, repeating injection of the first source precursor and the second source precursor onto the surface of the substrate without injecting the seed precursor.

10. An apparatus for depositing a material on a substrate, the apparatus comprising:
a first reactor configured to inject a seed precursor onto a surface of the substrate;
a second reactor adjacent to the first reactor and configured to inject a first source precursor onto the substrate, the first source precursor reacting with the seed precursor to generate a first reactant precursor on the surface of the substrate; and
a third reactor adjacent to the second reactor and configured to inject a second source precursor onto the substrate, the second source precursor reacting with the first reactant precursor on the surface of the substrate to deposit the material on the surface of the substrate.

11. The apparatus of claim 10, further comprising:
a fourth reactor adjacent to the third reactor and configured to inject a second reactant precursor onto the surface of the substrate after the third reactor injects the second source precursor onto the surface of the substrate, the second reactant precursor reacting with the second source precursor to deposit the material on the surface of the substrate.

12. The apparatus of claim 11, wherein the second reactant precursor comprises radicals generated from an oxygen-containing species.

13. The apparatus of claim 10, further comprising:
a fifth reactor adjacent to the first reactor and configured to inject hydroxyl radicals onto the substrate prior to the first reactor injecting the seed precursor onto the substrate, the hydroxyl radicals generating hydroxylated termination sites on the surface of the substrate;
wherein the seed precursor reacts with the hydroxylated termination sites to generate an intermediate compound and the first source precursor reacts with the intermediate compound to generate the first reactant precursor.

14. The apparatus of claim 10, further comprising:
an actuator configured to cause relative movement between the substrate and the first reactor, the second reactor, and the third reactor.

15. The apparatus of claim 10, wherein the material is deposited on the surface of the substrate by atomic layer deposition (ALD).

16. The apparatus of claim 10, wherein the first source precursor is an aluminum-containing metalorganic precursor and the first source precursor is a silanol, and wherein the first reactant precursor is H₂O.

17. The apparatus of claim 10, wherein the second source precursor comprises one selected from the group consisting of TMA, 3DMAS, TiCl₄, TDMAT, TEMAZr, and MeCpPtMe₃.
